(19) United States
(12) Patent Application Publication
(10) Pub. No.: US 2003/0168976 A1
(43) Pub. Date: Sep. 11, 2003

(54) Organic electroluminescent panel and a manufacturing method thereof

(75) Inventors: Kazuki Nishimura, Osaka (JP); Yuji Hamada, Ikoma-gun (JP)

Correspondence Address: McDERMOTT, WILL & EMERY, 600 13th Street, N.W., Washington, DC, 20005-3096, US

(73) Assignee: Sanyo Electric Co., Ltd.

(21) Appl. No.: 10/378,880

(22) Filed: Mar. 5, 2003

(30) Foreign Application Priority Data
Mar. 5, 2002 (JP) JP2002-059593

(51) Int. Cl. H01J 1/62

(52) U.S. Cl. 313/512

(57) ABSTRACT

A high-quality organic EL panel is provided. The organic EL panel that can withstand a temperature change is manufactured by making both a glass substrate and a protection body protecting an organic EL device of a glass material. By making both the protection body and the glass substrate of a glass material, not only can an overall thickness be reduced in comparison with a case of using a metal case, but also a degree of freedom can be heightened drastically in selecting an adhesive used to fix the two substrates in comparison with a case of using a metal case.

### BACKGROUND OF THE INVENTION

1. Field of the Invention

The present invention relates to an organic electroluminescent panel and a manufacturing method thereof, and more particularly to an organic electroluminescent panel having a protection body for protecting an organic electroluminescent device and a manufacturing method thereof.

2. Description of the Related Art

An organic electroluminescent panel (hereinafter, also referred to as “organic EL panel”) is self-luminous and therefore has better visibility than a liquid crystal panel. Since it does not need a backlight, it can be a thin and light display panel. Hence, the organic EL panel attracts attention as a panel that will take over the liquid crystal panel in the near future. In general, an organic electroluminescent device (hereinafter, also referred to as “organic EL device”) provided to the organic EL panel emits light through recombination of electrons injected from an electron injecting electrode to an electron transporting layer with holes injected from a hole injecting electrode to a hole transporting layer at the interface between the organic luminescent layer and the hole transporting layer or inside of the organic luminescent layer in the vicinity of the interface. A color organic EL device is manufactured by forming organic luminescent layers of respective colors by evaporating organic materials emitting red, green, and blue light, respectively.

FIG. 1 is a view showing a configuration of a conventional organic EL panel 20. The organic EL panel 20 has the configuration in which a metal case 14 made of a metal material is fixed to a glass substrate 10 on which an organic EL device 12 of a lamination structure is formed, and a desiccant seal 16 is stuck to the inner surface of the metal case 14. The metal case 14 functions as a protection body that prevents oxygen- or water-caused deterioration of the organic EL device 12.

However, a coefficient of thermal expansion of the metal case 14 is extremely large in comparison with a coefficient of thermal expansion of the glass substrate 10. Due to the difference of the coefficients, when an external temperature rises, the metal case 14 expands more than the glass substrate 10, which causes deflection of the glass substrate 10. Such deflection of the glass substrate 10 gives rise to deformation of the organic EL device 12, which results in a defect, such as a pin-hole, in the cathode and may further cause a dark spot.

The metal case 14 and the glass substrate 10 are generally fixed to each other through an adhesive. However, when objects made of different materials are bonded together, a degree of freedom in selecting an adhesive is limited. To be more specific, when the metal case 14 is fixed to the glass substrate 10, it is necessary to select an adhesive having good bonding property for both the metal material and the glass material. However, there arises a problem that sufficient bonding strength is not attained when an inappropriate adhesive is selected, or an adhesive that satisfies the need is too expensive.

### SUMMARY OF THE INVENTION

It is therefore an object of the invention to provide an organic EL panel capable of solving the above problems and a manufacturing method thereof.

In order to achieve the above and other objects, a first aspect of the invention provides an organic electroluminescent panel, including an organic electroluminescent device formed on a substrate, having an organic luminescent layer interposed between opposing electrodes, and a protection body for protecting an outside surface of the organic electroluminescent device, wherein the substrate and the protection body are made of glass.

By making both the substrate and the protection body of the same material, parameters indicating the thermal physical property, such as specific heat, thermal conductance, and a coefficient of linear expansion, become almost equal in the substrate and the protection body. This can reduce residual thermal stress held inside of them. Consequently, the organic electroluminescent device undergoes a lower degree of deformation even when an external temperature changes, which makes it possible to reduce a possibility of deterioration in luminous efficiency of the organic electroluminescent device.

By making the protection body of glass, it is possible to achieve a multiple pattern, that is, a plurality of organic EL panels are formed on a single glass substrate while protection bodies for the respective panels are formed also on another glass substrate, and the two substrates are fixed to each other, from which organic EL panels are cut out individually. The achievement of the multiple pattern is attributed to the configuration that the protection bodies are made of glass that can be cut. Consequently, a plurality of organic EL panels can be manufactured at a time, which makes it possible to cut the manufacturing cost drastically.

Since both the substrate and the protection body are made of the same material in the invention, a degree of freedom can be heightened in selecting an adhesive used to fix the substrate to the protection body. The used adhesive only has to fix glass to glass, and thus, a range of applicable adhesives is broadened in comparison with a case of using the protection body made of a metal case. This makes it possible to use a less expensive adhesive having higher bonding strength. When a UV curable adhesive is used as the adhesive, UV rays can be irradiated from either or both sides of the substrate and the protection body both made of glass. This offers a merit that an uncured portion is hardly left in the adhesive.

It is preferable that the protection body is provided to the substrate so as to define a space by an inner surface of the protection body and the organic electroluminescent device, and that a desiccant layer is provided onto the inner surface of the protection body. Also, in terms of the strength of the protection body and a reduced overall thickness, it is preferable that a thickness of the protection body is 0.1 mm or greater and 1 mm or less.

A second aspect of the invention provides a method of manufacturing an organic electroluminescent panel, the method including: forming a plurality of organic electroluminescent devices on a first glass substrate, each organic electroluminescent device having an organic luminescent layer interposed between opposing electrodes; etching a surface of a second glass substrate in accordance with a layout of the plurality of organic electroluminescent devices formed on the first glass substrate; forming a composite glass body by fixing a surface of the first glass substrate, on which the organic electroluminescent devices are formed, to the surface of the second glass substrate, to which etching is applied; and dividing the composite glass body into respective organic electroluminescent panels. According to this manufacturing method, it is possible to manufacture a plurality of organic electroluminescent panels from a single substrate.

It is to be noted that any arbitrary combination of the above-described structural components, and expressions changed between a method, an apparatus, a system and so forth are all effective as and encompassed by the present embodiments.

Moreover, this summary of the invention does not necessarily describe all necessary features so that the invention may also be sub-combination of these described features.

### BRIEF DESCRIPTION OF THE DRAWINGS

FIG. 1 is a view showing a configuration of a conventional organic EL panel;

FIG. 2 is a view showing a configuration of an organic EL panel according to one embodiment of the invention;

FIG. 3A includes a front view and a cross section showing a substrate on which a plurality of organic EL devices are formed;

FIG. 3B includes a front view and a cross section showing a substrate on which a plurality of space regions are formed; and

FIG. 3C is a view showing a configuration that the two substrates are stuck to each other.

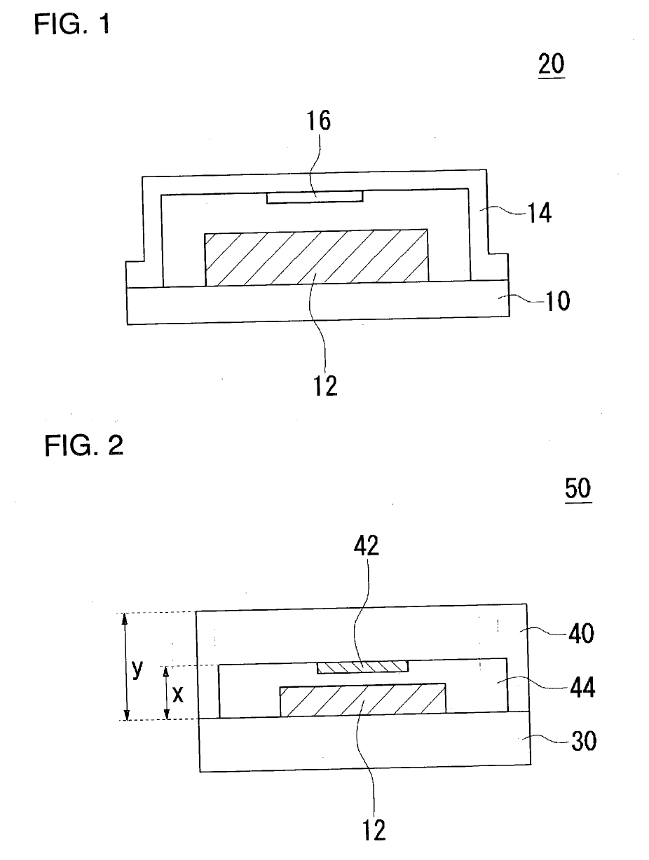

### DETAILED DESCRIPTION OF THE INVENTION

The invention will now be described based on preferred embodiments which do not intend to limit the scope of the present invention but exemplify the invention. All of the features and the combinations thereof described in the embodiments are not necessarily essential to the invention.

FIG. 2 is a view showing a configuration of an organic EL panel 50 according to one embodiment of the invention. The organic EL panel 50 includes a substrate 30, an organic EL device 12, a protection body 40, and a desiccant layer 42. The organic EL device 12 is of a lamination structure in which an organic luminescent layer is interposed between the opposing electrodes, and is formed on the substrate 30. The protection body 40 is also provided on the substrate 30, and forms a sealing structure together with the substrate 30 to protect the outside surface of the organic EL device 12 from outside air. A sealed space is defined by the inner surface of the protection body 40 and the organic EL device 12. This space is filled with an inert gas.

Both the substrate 30 and the protection body 40 are made of glass. This makes it possible to prevent excessive expansion or contraction of one with respect to the other when a temperature changes, and a possibility of the occurrence of a defect in the organic EL device 12 can be thus reduced. In general, a coefficient of thermal expansion of glass is within a range from 3 to 10×10⁻⁶/° C., and coefficients of thermal expansion of objects made of glass are almost equal. The protection body 40 made of a glass material can reduce an overall thickness in comparison with a case of using a metal case.

In order to maintain physical strength of the organic EL panel 50, it is preferable that a thickness (y−x) of the protection body 40 is 0.1 mm or greater. Herein, y is the height of the protection body 40 and x is the height of a space region 44. In particular, since the protection body 40 is made of a glass material, it is preferable to set the thickness (y−x) to 0.3 mm or greater. On the other hand, however, in order to reduce the thickness of the organic EL panel 50, it is preferable to set the thickness (y−x) of the protection body 40 to 1 mm or less. Further, in terms of maintaining the strength of the protection body 40 and reducing an overall thickness, it is preferable to set a ratio of the height y of the protection body 40 to the height x of the space region 44 as follows: 0.4≦x/y≦0.6.

The desiccant layer 42 is formed by applying a desiccant on the inner surface of the protection body 40 and then removing the solvent. The desiccant layer 42 may be formed by spraying a desiccant to the inner surface of the protection body 40, and it is obvious to those skilled in the art that the desiccant layer 42 can be formed through any other applicable method. Since the protection body 40 is made of a glass material, a conventionally used desiccant seal is not readily stuck to the inner surface. For this reason, it is preferable to form the desiccant layer 42 of a desiccant as described above.

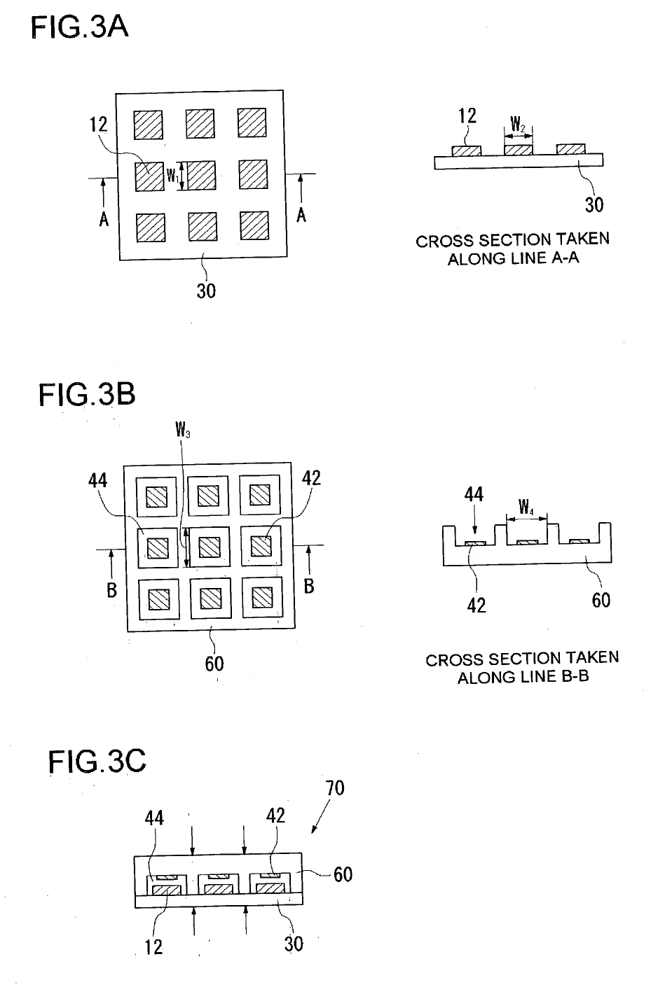

FIGS. 3A through 3C are views showing a manufacturing sequence of the organic EL panel 50. According to this example, a plurality of organic EL panels 50 are manufactured from a single substrate 30. The following description will describe the process of manufacturing organic EL panels 50 from a single glass substrate 30 for the organic EL devices 12 and a single glass substrate 60 for the protection bodies 40.

FIG. 3A shows the substrate 30 on which a plurality of (3×3) organic EL devices 12 are formed. Here, the organic EL device 12 has an organic luminescent layer interposed between the opposing electrodes. It is preferable to form these organic EL devices 12 at certain intervals. Each of the organic EL devices 12 is of a size having the length W₁ and the width W₂.

FIG. 3B shows the substrate 60 on which a plurality of (3×3) space regions 44 are formed. In this step, the space regions 44 are formed by etching the surface of the substrate 60 in accordance with the layout of the plurality of organic EL devices 12 formed on the substrate 30. Each space region 44 is of a size having the length W₃, the width W₄, and the depth deeper than the height of the organic EL device 12, that is, a height from the surface of the substrate 30 to the top surface of the organic EL device 12. Also, the length W₃ and the width W₄ of the space region 44 are longer than the length W₁ and the width W₂ of the organic EL device 12, respectively. The desiccant layer 42 is provided onto the inner surface of the space region 44 by, for example, applying a desiccant.

FIG. 3C is a view showing a configuration that the substrate 30 and the substrate 60 are stuck to each other. In this step, a composite glass body 70 is obtained by fixing the surface of the substrate 30 to the surface of the substrate 60 with an adhesive or the like, wherein on the surface of the substrate 30 the organic EL devices 12 are formed and on the surface of the substrate 60 the space regions 44 are formed through etching. As shown in the drawing, each organic EL device 12 is accommodated as being sealed in the space region 44 to which the desiccant layer 42 is provided. Subsequently, the composite glass body 70 is divided into the respective organic EL panels 50 with a diamond cutter at the positions indicated by arrows in the drawing. A plurality of organic EL panels 50 that can withstand a temperature change can be manufactured from the single substrate 30 through the steps described above.

While preferred embodiments of the invention have been described, it is to be understood that the technical scope of the invention is not limited to the description in the above. The embodiments above are given solely by way of illustration. It will be understood by those skilled in the art that various modifications may be made to combinations of the foregoing components and processes, and all such modified examples are also intended to fall within the scope of the invention.

What is claimed is:

1. An organic electroluminescent panel, comprising:
an organic electroluminescent device formed on a substrate, having an organic luminescent layer interposed between opposing electrodes; and
a protection body for protecting an outside surface of the organic electroluminescent device,
the substrate and the protection body being made of glass.

2. An organic electroluminescent panel according to claim 1, further comprising a desiccant layer provided onto an inner surface of the protection body.

3. An organic electroluminescent panel according to claim 1 or 2, wherein a thickness of the protection body is 0.1 mm or greater and 1 mm or less.

4. A method of manufacturing an organic electroluminescent panel, the method including:
forming a plurality of organic electroluminescent devices on a first glass substrate, each organic electroluminescent device having an organic luminescent layer interposed between opposing electrodes;
etching a surface of a second glass substrate in accordance with a layout of the plurality of organic electroluminescent devices formed on the first glass substrate;
forming a composite glass body by fixing a surface of the first glass substrate, on which the organic electroluminescent devices are formed, to the surface of the second glass substrate, to which etching is applied; and
dividing the composite glass body into respective organic electroluminescent panels.

5. A method according to claim 4, wherein a desiccant layer is provided onto a surface of the second glass substrate, to which etching is applied.

6. A method according to claim 4, wherein a thickness of the etched second glass substrate is 0.1 mm or greater and 1 mm or less.
